(19) United States
(12) Patent Application Publication
(10) Pub. No.: US 2026/0277111 A1
(43) Pub. Date: Sep. 17, 2026

(54) FLUID HANDLING SYSTEM AND METHOD, AND METHOD OF MANUFACTURING DEVICES

(71) Applicant: ASML NETHERLANDS B.V., Veldhoven (NL)

(72) Inventors: Antonius Johannus VAN DER NET, Tilburg (NL); Justin Johannes Hermanus GERRITZEN, Veldhoven (NL); Ruud Hendrikus Martinus Johannes BLOKS, Helmond (NL); Milena JOVANOVIC, Eindhoven (NL); Shruthi NAYAK KALLARBAIL, Eindhoven (NL); Giovaanni Luca GATTOBIGIO, Eindhoven (NL)

(73) Assignee: ASML NETHERLANDS B.V., Veldhoven (NL)

(21) Appl. No.: 19/472,041

(22) PCT Filed: Mar. 5, 2024
(86) PCT No.: PCT/EP2024/055657

§ 371 Date: Oct. 2, 2025

(30) Foreign Application Priority Data
Apr. 4, 2023 (EP) 23166578.7
Jan. 18, 2024 (EP) 24152615.1

(51) Int. Cl. G03F 7/00

(52) U.S. Cl. CPC G03F 7/70341

(57) ABSTRACT

A fluid handling system for a lithographic system, the fluid handling system including: a liquid supply configured to supply immersion liquid to fill at least a portion of an immersion space between a substrate and a projection system of the lithographic system, the projection system configured project a patterned radiation beam onto the substrate; a gas supply configured to generate a gas jet for confining the immersion liquid within the immersion space, the gas jet including a medium; an evacuation system including an evacuation passage, the evacuation system configured to draw a two-phase fluid including the medium and the immersion liquid into the evacuation passage, and the two-phase fluid has a gas phase and a liquid phase; and a recycling system configured to receive the two-phase fluid from the evacuation passage, and to extract the medium from the two-phase fluid as a product fluid for further use.

### CROSS-REFERENCE TO RELATED APPLICATIONS

This application claims priority of EP application 23166578.7 which was filed on 4 Apr. 2023 and of EP application 24152615.1 which was filed on 18 Jan. 2024 and which are incorporated herein in their entirety by reference.

### FIELD

The present invention relates to a fluid handling system, a method of handling fluid, and a method of manufacturing devices.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer). Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti-parallel to this direction.

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm.

Further improvements in the resolution of smaller features may be achieved by providing an immersion fluid having a relatively high refractive index, such as water, on the substrate during exposure. The effect of the immersion fluid is to enable imaging of smaller features since the exposure radiation will have a shorter wavelength in the fluid than in gas. The effect of the immersion fluid may also be regarded as increasing the effective numerical aperture (NA) of the system and also increasing the depth of focus.

The immersion fluid may be confined to a localized area between the projection system of the lithographic apparatus and the substrate by a fluid handling structure. In an immersion lithography apparatus, gas flows may be used to control the immersion fluid. For example, gas knives may be used to confine immersion liquid to a space between the final element of the projection system and the substrate or substrate support.

As lithography technologies develop and as the demand for semiconductors increase, it is recognized that the semiconductor industry may be a significant contributor to climate change.

### SUMMARY OF THE INVENTION

It is an object of the present invention to reduce the semiconductor industry's contribution to climate change.

According to an aspect of the present invention, there is provided a fluid handling system for a lithographic system, the fluid handling system comprising:
a liquid supply configured to supply an immersion liquid to fill at least a portion of an immersion space between a substrate and a projection system of the lithographic system, wherein the projection system is configured project a patterned radiation beam onto the substrate;
a gas supply configured to generate a gas jet for confining the immersion liquid within the immersion space, wherein the gas jet comprises a medium; and
an evacuation system comprising an evacuation passage, wherein the evacuation system is configured to draw a two-phase fluid comprising the medium and the immersion liquid into the evacuation passage, and the two-phase fluid comprises a gas phase and a liquid phase;
a recycling system configured to receive the two-phase fluid from the evacuation passage, and to extract the medium from the two-phase fluid as a product fluid for further use.

According to another aspect of the present invention, there is provided a method comprising:
supplying an immersion liquid to fill at least a portion of an immersion space between a substrate and a projection system of a lithographic system, which projection system projects a patterned radiation beam onto the substrate;
supplying gas to generate a gas jet which confines the immersion liquid within the immersion space, wherein the gas jet comprises a medium;
drawing a two-phase fluid comprising the medium and the immersion liquid into an evacuation passage, wherein the two-phase fluid comprises a gas phase and a liquid phase; and
extracting the medium from the two-phase fluid as a product fluid for further use.

### BRIEF DESCRIPTION OF THE DRAWINGS

Embodiments of the invention will now be described, by way of example only, with reference to the accompanying schematic drawings, in which corresponding reference symbols indicate corresponding parts.

FIG. 1 depicts the schematic overview of a lithographic apparatus;

FIG. 2 depicts a fluid handling system for a lithographic system;

FIG. 3 depicts a fluid handling system for a lithographic system;

FIG. 4 depicts a fluid handling system for a lithographic system;

FIG. 5 depicts a liquefaction unit;

FIG. 6 depicts a membrane separation unit; and

FIG. 7 depicts a pressure swing adsorption unit.

The features shown in the Figures are not necessarily to scale, and the size and/or arrangement depicted is not limiting. It will be understood that the Figures include optional features which may not be essential to the invention. Furthermore, not all of the features of the apparatus are depicted in each of the figures, and the Figures may only show some of the components relevant for describing a particular feature.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

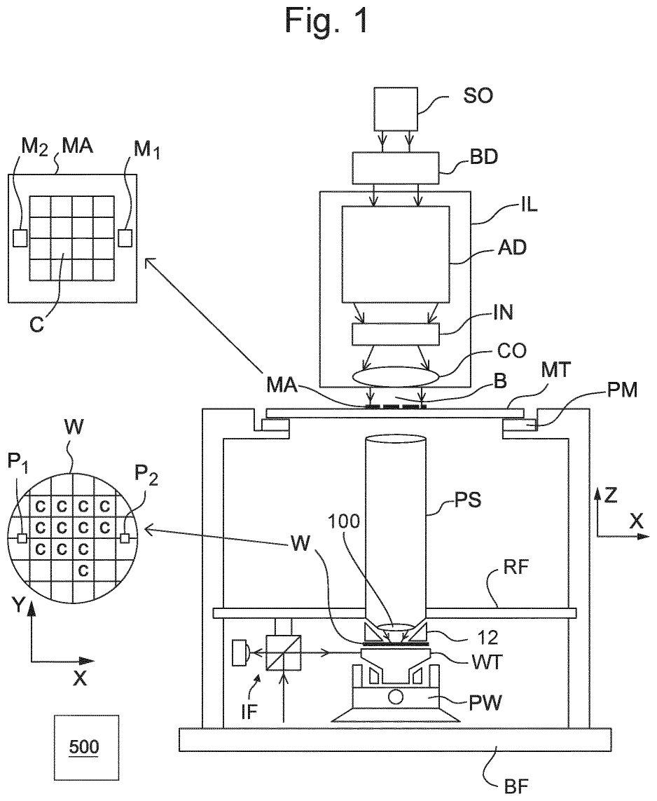

FIG. 1 schematically depicts a lithographic apparatus. The lithographic apparatus includes an illumination system (also referred to as illuminator) IL configured to condition a radiation beam B (e.g., UV radiation or DUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a substrate table) WT constructed to hold a substrate (e.g., a resist coated wafer) W and connected to a second positioner PW configured to accurately position the substrate support WT in accordance with certain parameters, and a projection system (e.g., a refractive projection lens system) PS configured to project a pattern imparted to the radiation beam B by patterning device MA onto a target portion C (e.g., comprising one or more dies) of the substrate W. A controller 500 controls the overall operation of the apparatus. Controller 500 may be a centralised control system or a system of multiple separate sub-controllers within various sub-systems of the lithographic apparatus.

In operation, the illumination system IL receives the radiation beam B from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus is of a type wherein at least a portion of the substrate W may be covered by an immersion liquid having a relatively high refractive index, e.g., water, so as to fill an immersion space 11 between the projection system PS and the substrate W—which is also referred to as immersion lithography. More information on immersion techniques is given in U.S. Pat. No. 6,952,253, which is incorporated herein by reference.

The lithographic apparatus may be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus may comprise a measurement stage (not depicted in figures). The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

To clarify the invention, a Cartesian coordinate system is used. The Cartesian coordinate system has three axis, i.e., an x-axis, a y-axis and a z-axis. Each of the three axis is orthogonal to the other two axis. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

Immersion techniques have been introduced into lithographic systems to enable improved resolution of smaller features. In an immersion lithographic apparatus, a liquid layer of immersion liquid having a relatively high refractive index is interposed in the immersion space 11 between a projection system PS of the apparatus (through which the patterned beam is projected towards the substrate W) and the substrate W. The immersion liquid covers at least the part of the substrate W under a final element of the projection system PS. Thus, at least the portion of the substrate W undergoing exposure is immersed in the immersion liquid.

In commercial immersion lithography, the immersion liquid is water. Typically the water is distilled water of high purity, such as Ultra-Pure Water (UPW) which is commonly used in semiconductor fabrication plants. In an immersion system, the UPW is often purified and it may undergo additional treatment steps before supply to the immersion space 11 as immersion liquid. Other liquids with a high refractive index can be used besides water as the immersion liquid, for example: a hydrocarbon, such as a fluorohydrocarbon; and/or an aqueous solution. Further, other fluids besides liquid have been envisaged for use in immersion lithography.

In this specification, reference will be made in the description to localized immersion in which the immersion liquid is confined, in use, to the immersion space 11 between the final element 100 and a surface facing the final element 100. The facing surface is a surface of substrate W or a surface of the supporting stage (or substrate support WT) that is co-planar with the surface of the substrate W. (Please note that reference in the following text to surface of the substrate W also refers in addition or in the alternative to the surface of the substrate support WT, unless expressly stated otherwise; and vice versa). A fluid handling structure 12 present between the projection system PS and the substrate support WT is used to confine the immersion liquid to the immersion space 11. The immersion space 11 filled by the immersion liquid is smaller in plan than the top surface of the substrate W and the immersion space 11 remains substantially stationary relative to the projection system PS while the substrate W and substrate support WT move underneath.

Other immersion systems have been envisaged such as an unconfined immersion system (a so-called ‘All Wet’ immersion system) and a bath immersion system. In an unconfined immersion system, the immersion liquid covers more than the surface under the final element 100. The liquid outside the immersion space 11 is present as a thin liquid film. The liquid may cover the whole surface of the substrate W or even the substrate W and the substrate support WT co-planar with the substrate W. In a bath type system, the substrate W is fully immersed in a bath of immersion liquid.

The fluid handling structure 12 is a structure which supplies the immersion liquid to the immersion space 11, removes the immersion liquid from the immersion space 11 and thereby confines the immersion liquid to the immersion space 11. It includes features which are a part of a fluid supply system. The arrangement disclosed in PCT patent application publication no. WO 99/49504 is an early fluid handling structure comprising pipes which either supply or recover the immersion liquid from the immersion space 11 and which operate depending on the relative motion of the stage beneath the projection system PS. In more recent designs, the fluid handling structure extends along at least a part of a boundary of the immersion space 11 between the final element 100 of the projection system PS and the substrate support WT or substrate W, so as to in part define the immersion space 11.

The fluid handing structure 12 may have a selection of different functions. Each function may be derived from a corresponding feature that enables the fluid handling structure 12 to achieve that function. The fluid handling structure 12 may be referred to by a number of different terms, each referring to a function, such as barrier member, seal member, fluid supply system, fluid removal system, liquid confinement structure, etc.

Immersion liquid can be used as the immersion fluid. In that case the fluid handling structure 12 may be a liquid handling system. In reference to the aforementioned description, reference in this paragraph to a feature defined with respect to fluid may be understood to include a feature defined with respect to liquid.

A lithographic apparatus has a projection system PS. During exposure of a substrate W, the projection system PS projects a beam of patterned radiation onto the substrate W. To reach the substrate W, the path of the radiation beam B passes from the projection system PS through the immersion liquid confined by the fluid handling structure 12 between the projection system PS and the substrate W. The projection system PS has a lens element, the last in the path of the beam, which is in contact with the immersion liquid. This lens element which is in contact with the immersion liquid may be referred to as ‘the last lens element’ or “the final element”. The final element 100 is at least partly surrounded by the fluid handling structure 12. The fluid handling structure 12 may confine the immersion liquid under the final element 100 and above the facing surface.

The lithographic apparatus, including the fluid handling structure 12, may be variously implemented, e.g. in accordance with European patent application number 23156328.9 (filed on 13 Feb. 2023), U.S. Pat. Nos. 7,379,155 B2 or 7,481,867 B2, each of which is herein incorporated by reference in its entirety.

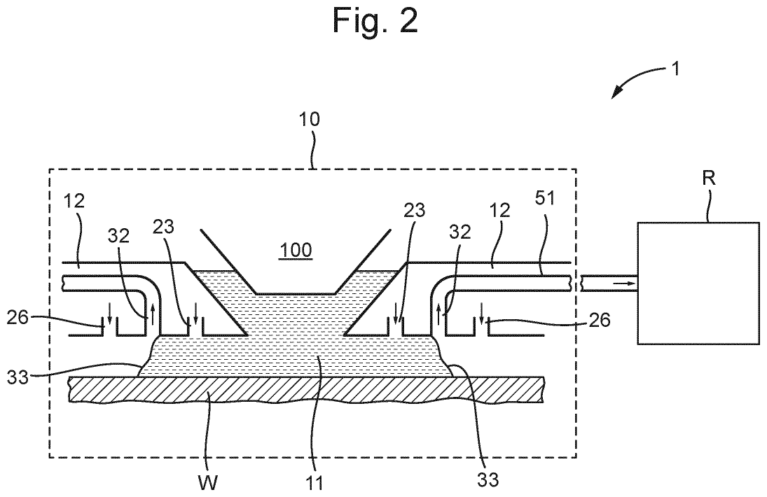

Referring now to FIG. 2, the fluid handling system 1 comprises a liquid supply configured to supply an immersion liquid to fill at least a portion of an immersion space 11 between a substrate W and a projection system PS of the lithographic system 10. The projection system PS, as described above with reference to FIG. 1, is configured project a patterned radiation beam B onto the substrate W. The fluid handling system 1 comprises a gas supply configured to generate a gas jet for confining the immersion liquid within the immersion space 11. The gas jet comprises a medium.

Furthermore, the fluid handling system 1 comprises an evacuation system comprising an evacuation passage 51. The evacuation system is configured to draw a two-phase fluid comprising the medium and the immersion liquid into the evacuation passage 51. The two-phase fluid comprises a gas phase and a liquid phase. The gas phase may be predominantly composed of the medium. However, it is to be understood that, in the two-phase fluid present in the evacuation passage 51, the gas phase may not be purely composed of the medium. For example, the gas phase may include gasses (e.g. air) drawn in from the environment surrounding the substrate W or substrate support WT. The gas phase may also include vapour of the immersion liquid. Likewise, the liquid phase in the two-phase fluid present in the evacuation passage 51 may not be purely composed of the immersion liquid. In particular, some of the medium from the gas jet may have been dissolved in the immersion liquid. Furthermore, the gas phase and the liquid phase may take up any portion of the two-phase fluid. For example, the gas phase may take up a majority of the volume of the two-phase fluid, or the liquid phase may take up a majority of the volume of the two-phase fluid. The liquid phase and the gas phase may alternatively take up roughly half of the volume of the two-phase fluid.

It is also to be understood that, due to fluid dynamical interactions between the gas phase and the liquid phase as the two-phase fluid is drawn into the evacuation passage 51, the gas phase and the liquid phase may not be present as distinct streams of fluids, and may instead be mixed together to some extent. More particularly, some of the liquid phase may be present as liquid droplets suspended in the gas phase, and/or some of the gas phase may be present as gas bubbles in the liquid phase. The gas phase and the liquid phase may also be dynamically and/or turbulently mixed so that the gas phase and the liquid phase do not have time to form stable bubbles or droplets.

The fluid handling system 1 further comprises a recycling system R. The recycling system R is configured to receive the two-phase fluid from the evacuation passage 51, and to extract the medium from the two-phase fluid as a product fluid for further use. Specifically, the recycling system R may be configured to receive the two-phase fluid directly from the evacuation passage 51. The recycling system R may be configured to receive the two-phase fluid without allowing other fluids (e.g. air or water) from being added to, or otherwise coming into contact with, the two-phase fluid before the two-phase fluid reaches the recycling system R. Once extracted from the immersion space 11, the two-phase fluid may be transported to the recycling system R without coming into contact with other fluids (e.g. air or water). The evacuation passage 51 may be enclosed. In particular, the evacuation passage 51 may fluidly connect the immersion space 11 and the recycling system R in a substantially fluid-tight manner. For example, the evacuation passage 51 may be without any section which is open to the atmosphere, or to an environment where other fluids are present. In addition to ensuring efficient recovery of the medium, this may also improve personnel safety. Specifically, certain medium, such as carbon dioxide, can be toxic to humans given sufficient concentration and length of exposure. Therefore, it may be undesirable for safety reasons to allow the medium to escape, or to be vented, to the atmosphere.

This, of course, does not necessarily imply that the evacuation passage 51 has a constant cross-section throughout its length. The evacuation passage 51 may comprise various additional elements along its length as required, for example valves, pressure regulators, pumps, compressors, heat exchangers, filters, buffer tanks, etc.

In any event, the totality of the extracted two-phase fluid may be transported from the immersion space 11 to the recycling system R substantially without any loss or dilution of the two-phase fluid.

In more detail, by way of a non-limiting example only, FIG. 2 shows a fluid handling structure 12 (which may be part of the fluid handling system 1) around the bottom surface of the final element 100 of the projection system PS. The final element 100 may have an inverted frusto-conical shape. The frusto-conical shape may have a planar bottom surface and a conical surface. The frusto-conical shape may protrude from a planar surface and may have a bottom planar surface. The bottom planar surface may be the optically active portion of the bottom surface of the final element 100, through which the radiation beam B may pass. The fluid handling structure 12 may surround at least part of the frusto-conical shape. The fluid handling structure 12 may have an inner-surface which faces towards the conical surface of the frusto-conical shape. The inner-surface and the conical surface may have complementary shapes. A top surface of the fluid handling structure 12 may be substantially planar. The fluid handling structure 12 may fit around the frusto-conical shape of the final element 100. A bottom surface of the fluid handling structure 12 may be substantially planar and in use the bottom surface may be parallel with the facing surface of the substrate support WT and/or substrate W. Thus, the bottom surface of the fluid handling structure 12 may be referred to as a surface facing the surface of the substrate W. The distance between the bottom surface and the facing surface may be in the range of 20 to 500 micrometers, desirably in the range of 70 to 200 micrometers.

The fluid handling structure 12 may extend closer to the facing surface of the substrate W and substrate support WT than the final element 100. The immersion space 11 may therefore be defined between the inner surface of the fluid handling structure 12, the planar surface of the frusto-conical portion and the facing surface. During use, the immersion space 11 is filled with immersion liquid. The immersion liquid fills at least part of a buffer space between the complementary surfaces between the final element 100 and the fluid handling structure 12, e.g. at least part of the space between the complementary inner-surface and the conical surface.

The immersion liquid may be supplied to the immersion space 11 through an opening formed in a surface of the fluid handling structure 12. The immersion liquid may be supplied through a supply opening (not shown) in the inner-surface of the fluid handling structure 12. Alternatively or additionally, the immersion liquid is supplied from an under supply opening 23 formed in the bottom surface of the fluid handling structure 12. The under supply opening 23 may surround the path of the radiation beam B and it may be formed of a series of openings in an array or a single slit. The immersion liquid is supplied to fill the immersion space 11 so that flow through the immersion space 11 under the projection system PS is laminar. The supply of the immersion liquid from the under supply opening 23 additionally prevents the ingress of bubbles into the immersion space 11. This supply of the immersion liquid may function as a liquid seal.

A extraction opening may serve to hold a meniscus 33 of the immersion liquid to the fluid handling structure 12. Alternatively or additionally, the immersion liquid may be extracted through a recovery opening (not shown) in the inner-surface of the fluid handling structure 12. The meniscus 33 forms between the fluid handling structure 12 and the facing surface and it serves as border between the liquid space and the gaseous external environment. The extraction opening in the bottom surface may be formed as a series of pinning openings 32 through which the two-phase fluid is extracted. The pinning openings may be connected to the evacuation passage 51. FIG. 2 schematically shows that the evacuation passage 51 is connected to one pinning opening 32, but it should be understood that some or all of the pinning openings 32 may be connected to the evacuation passage 51.

It should be understood that the supply opening and recovery opening in the inner-surface of the fluid handling structure 12 can have their function swapped (i.e. the flow direction of liquid is reversed). This allows the direction of flow to be changed depending upon the relative motion of the fluid handling structure 12 and substrate W. And the recovery opening may be connected to the evacuation passage 51 in a way similar to the pinning openings 32.

Radially outward, with respect to the inner-surface of the fluid handling structure 12, may be a gas knife opening 26. The medium may be supplied through the gas knife opening 26 at elevated speed to form the gas jet, which may assist liquid confinement of the immersion liquid in the immersion space 11. The supplied gas may be humidified and it may contain substantially carbon dioxide.

As the meniscus 33 may be near or substantially at the pinning openings 32, the fluid extracted via the pinning openings 32 is generally a two-phase fluid, comprising the immersion liquid and the medium supplied through the gas knife opening 26.

Further openings, for example open to atmosphere or to a gas source or to a vacuum, may be present in the bottom surface of the fluid handling structure 12, i.e. in the surface of the fluid handling structure 12 facing the substrate W. For example, radially outward of the gas knife opening 26 may be a gas recovery opening (not shown) for recovering the medium supplied through the gas knife opening 26. As above, the gas recovered through the gas recovery opening may not be purely composed of the medium, and may instead include gasses (e.g. air) in the environment surrounding the substrate W or substrate support WT or even liquid remaining on the facing surface. The gas recovered through the gas recovery opening may be directed into the evacuation passage 51, and be combined with the two-phase fluid extracted into the evacuation passage 51.

Although use of immersion fluid/liquid is beneficial for improving resolution of smaller features on a substrate W, there are also challenges with the use of immersion fluid/liquid relating to defects being introduced on the substrate W.

In general, when immersion liquid is used, droplets of the immersion liquid may be left behind on the surface of the substrate W. The meniscus 33 at the edge of the immersion liquid may collide with any droplets on the surface of the substrate W. When a droplet hits the meniscus 33, gas may be entrapped within the immersion liquid. This results in a bubble in the immersion liquid. Formation of bubbles in the immersion liquid can lead to defects on the substrate W. Droplets that remain on the surface of the substrate W may cause drying spots and/or affect the chemical properties of the resist, also leading to defects.

Very small bubbles of gas may dissolve in the immersion liquid before they reach the exposure area of the immersion space 11. A bubble of carbon dioxide gas typically dissolves faster than a bubble of air. A bubble of CO₂, which has a solubility fifty-five times larger than that of nitrogen and a diffusivity of 0.86 times that of nitrogen, will typically dissolve in a time thirty-seven times shorter than the time for a bubble of the same size of nitrogen to dissolve. Supplying CO₂ adjacent to the meniscus 33 means that a bubble of CO₂ gas will dissolve into the immersion liquid much faster than if other gases with lower diffusivity were used. Therefore, using CO₂ in the fluid handling structure 12 is known to reduce the number of imaging defects thereby allowing higher throughput (e.g., higher speed of the substrate W relative to the fluid handling structure 12) and lower defectivity.

It may be desirable to maintain the temperature of the sensitive parts of the apparatus, e.g. the substrate support WT and the vicinity thereof, at a very precise target temperature. Evaporation of the immersion liquid in two-phase extraction flows is therefore an undesirable thermal load. To minimise this thermal load, it is desirable to use humidified gas in the fluid handling structure 12.

As noted above, the evacuation system is configured to draw the two-phase fluid into the evacuation passage 51. The evacuation system may provide the driving force for the removal of the two-phase fluid from the immersion space 11 between the fluid handling structure 12 and the substrate W via the evacuation passage 51. The operation of the liquid seal and its ability to carry out its function without excessive disturbance to the fluid handling structure 12, substrate W or immersion liquid, may depend on the quality of the gas flow around the liquid seal and may therefore depend on the pumping performance of the evacuation system. Examples of suitable implementations of the evacuation system are disclosed in U.S. Pat. No. 7,379,155 B2, which is herein incorporated by reference in its entirety. Other implementations of the evacuation system are possible provided that the liquid seal can be maintained, and that the two-phase fluid is drawn into the evacuation passage 51.

As noted above, as the semiconductor industry grows, its contribution towards climate change has become an increasing concern. Lithographic systems contributes to climate change in a variety of ways. The largest contribution generally comes from the generation of the electricity needed to power the lithographic apparatus. Therefore, continued efforts have been made to improve the power efficiency of the many components of a lithographic apparatus. However, aside from electrical power, a lithographic apparatus require other resources which also contribute to climate change. For example, cooling supplies, compressed air supplies, clear air supplies and clean water supplies all require energy to operate, and the maintenance of these supply systems also contribute to further consumption of energy and supplies. The energy cost associated with the manufacture of the various components of the lithographic apparatus itself is also a significant contributor to climate change.

As noted above, it may be advantageous to use carbon dioxide in the gas supply in immersion lithography owing to its high solubility in water. However, as found by the present inventors, in known immersion lithography techniques, the use of carbon dioxide in immersion lithography may also be a considerable contributor to climate change, albeit to a much smaller degree than the contribution from the electricity needed to power the lithography apparatus. Specifically, the use of carbon dioxide in known techniques may contribute to climate change principally in two ways, namely the direct release of the carbon dioxide into the atmosphere as a greenhouse gas, and the energy required in the production and transport of carbon dioxide supply. However, compared with carbon sequestration for power plants running on fossil fuels, for example, the volume of carbon dioxide involved in immersion lithography is many orders of magnitude smaller. As a result, within the general goal of slowing or stopping climate change, whereas much effort has been made to reduce the electrical consumption of the various components of a lithographic apparatus, the use of carbon dioxide in immersion lithography has so far evaded attention.

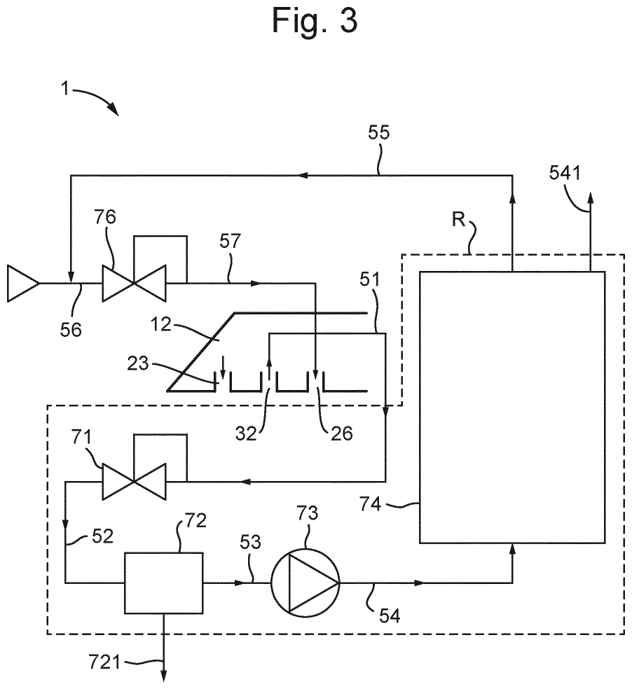

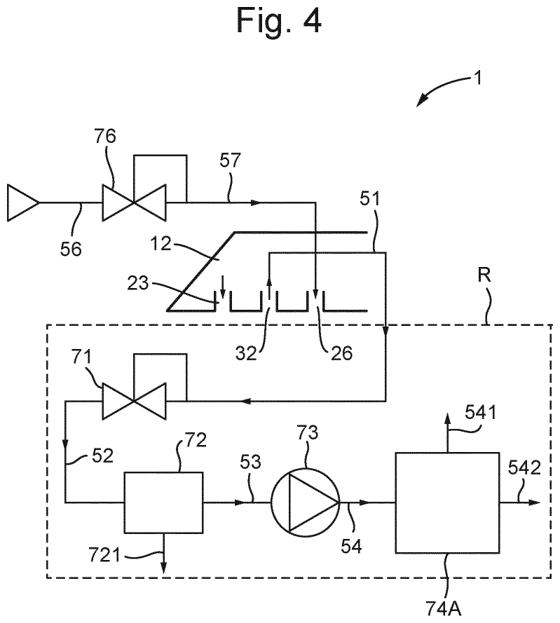

Referring now to FIG. 3, generally, the product fluid (containing the medium recycled by the recycling system R) may be fed back (via passage 55, as shown) to the gas supply in order to provide the medium to the gas supply. However, as an alternative, the product fluid may be used for other purposes, and/or may be stored. As yet another alternative, to be disclosed below with reference to FIG. 4, the medium in the product fluid may be converted into another substance.

Referring to FIG. 3 again, the recycling system R may comprise a separator 72 configured to separate the gas phase from the two-phase fluid. Therefore, the gas phase and the liquid phase of the two-phase fluid may be separated by the separator 72. However, the separation of the gas phase and the liquid phase need not be perfect. For example, although the gas phase separated by the separator 72 should be substantially devoid of liquid droplets, some of the smallest liquid droplets may continue to be present in the gas phase.

Different implementation of the separator 72 are possible. For example, a separator tank, such as disclosed in U.S. Pat. No. 7,379,155 B2, may be used. The separator tank may function by gravity, i.e. the liquid phase is allowed to collect in a bottom portion, leaving the gas phase in an upper portion from which it is transported away. The separator tank may be allow any liquid droplets to settle and be collected in the bottom portion. Alternatively or additionally, the separator 72 may comprise a chevron type separator. Alternatively or additionally, the separator 72 may comprise a cyclone separator.

The gas phase thus separated may be passed on to further processing via downstream passage 53. The liquid phase thus separated may be drained away via drain 721. Alternatively, the liquid phase may also be collected for further use. The two-phase fluid may flow through other components before reaching the separator 72. For example, the two-phase fluid may flow through a pressure regulator 71 before reaching separator 72.

The recycling system R is configured to extract the medium from the gas phase. Specifically, the recycling system may comprise a gas phase processing unit 74 configured to receive the separated gas phase from the separator 72. The gas phase processing unit 74 may be configured to extract the medium from the gas phase. As shown, a pump 73 may be present to transport the gas phase from the separator 72 towards the gas phase processing unit 74.

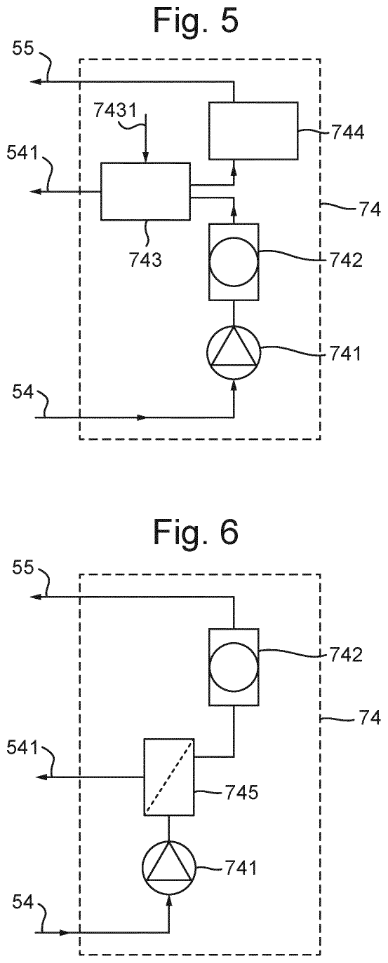

FIGS. 5 to 7 depict different implementations of the gas phase processing unit 74.

As shown, the recycling system R may comprise a compressor 741 configured to compress the gas phase. The compressor 741 may be part of the gas phase processing unit 74. The compressor 741 may receive the gas phase from the separator 72, or from pump 73 if present. Compression may be desired for further processing steps of the gas phase. Compression may also be necessary in case the extracted medium is to be fed back to the gas supply. More generally, compression may reduce the volume of the gas phase, so that downstream components may be more compact. As shown in FIGS. 5 and 6, a gas dryer 742 may also be included to reduce the relative humidity of the gas phase.

In arrangement shown in FIG. 5, the concentration of the medium is raised by liquefaction, also known as cryogenic separation. As shown, the gas phase is passed into a condensation chamber 743, in which the medium is allowed to condense into a liquid state. Coolant 7431 may be provided to the condensation chamber 743 to decrease the temperature of the gas phase. The decrease in temperature may cause the medium to condense into a liquid state. The liquefaction separates the medium (notably CO₂) from non-condensable gases, including O₂ and N₂. Non-condensable gasses may be exhausted as waste gas 541. The medium (in liquid state) may then be passed on to an evaporator 744, where it is allowed to evaporate back into gaseous form. In this case, as shown in FIG. 3, the medium in gaseous form may be fed back to the gas supply. Alternatively, the medium may remain in liquid form and be stored or transported away for further use. For example, the stored medium may be liquid carbon dioxide, which finds many uses in industry, such as for producing carbonated beverages, or for filling fire extinguishers.

Using liquefaction, the recycling system R may be capable of producing the medium at a high degree of purity. For example, the volumetric concentration of the medium in the product fluid, as measured at 1013 mbar absolute and 0° C., may be at least 99.9%, optionally at least 99.99%, optionally about 99.998%.

FIG. 6 shows another arrangement for raising the concentration of the medium. As shown, the concentration of the medium in this arrangement is raised by membrane separation. As shown, the recycling system R comprises a membrane separation unit 745. The membrane separation unit 745 may be part of the gas phase processing unit 74. The membrane separation unit 745 may separate the medium from the gas phase, producing waste gas 541 to be exhausted. A pressure drop may exist across the separation membrane. The compressor 741 may provide the necessary pressure rise to sustain the pressure drop across the separation membrane. Membrane separation may provide a simple and energy efficient means of raising the concentration of the medium.

As shown, the arrangement of FIG. 6 may also comprise a gas dryer 742. The gas dryer 742 may be placed downstream of the membrane separation unit 745. By placing the gas dryer 742 downstream, the gas phase entering the membrane separation unit 745 may have relatively high humidity. This may be advantageous as the performance of certain types of membrane separation units may be improved by being fed with humid gas.

Using the above membrane separation technique, the recycling system R may be capable of producing the medium at a high degree of purity. For example, the volumetric concentration of the medium in the product fluid, as measured at 1013 mbar absolute and 0° C., may be at least 99.9%, optionally at least 99.99%, optionally about 99.998%.

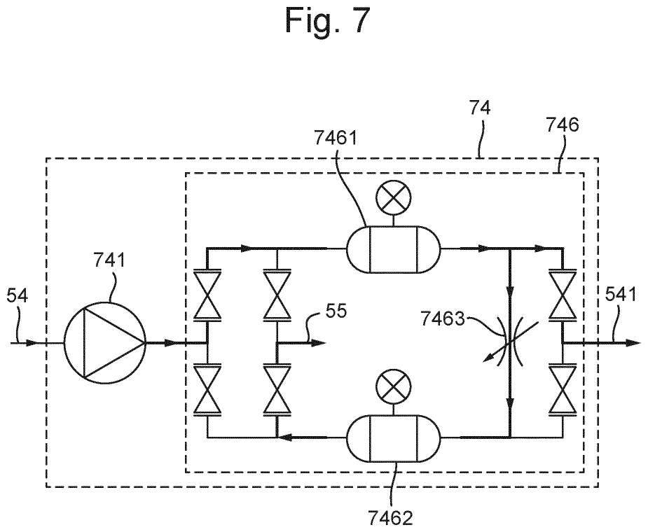

FIG. 7 shows a further arrangement for raising the concentration of the medium. As shown, the concentration of the medium in this arrangement is raised by pressure swing adsorption (PSA). The recycling system R may comprise a pressure swing adsorption unit 746 for this purpose. The pressure swing adsorption unit 746 may be part of the gas phase processing unit 74.

Using PSA, the medium may be separated from the gas phase by exploiting the fact that different gas species may have different molecular characteristics and affinity for an adsorbent material. In general, the higher the pressure, the more gas is adsorbed. When the pressure is dropped, the gas is released, i.e. desorbed. As the gas phase is passed under pressure through an adsorbent bed that attracts unwanted gasses such as nitrogen and oxygen, these will remain adsorbed in the bed, and the gas exiting the bed will have a higher concentration of the medium than the gas entering the bed. When the bed reaches the limit of its capacity to adsorb unwanted gasses, it can be regenerated by further decreasing the pressure, thus releasing the adsorbed unwanted gasses.

FIG. 7 shows a possible implementation of the pressure swing adsorption unit 746. As shown, the pressure swing adsorption unit 746 may comprise a first bed 7461 and a second bed 7462. The thick lines in FIG. 7 indicate flow paths that are open, wherein thin lines indicate flow paths that are closed. In the state shown, the first bed 7461 is at a relatively high pressure, wherein the second bed 7462 is at a relatively low pressure. As shown, the gas phase from the separator 72, via passage 54, is fed into the first bed 7461. As the first bed 7461 is at a high pressure, adsorption takes place. In the previous cycle, the second bed 7462 was at a high pressure and adsorption took place, but is now in a low pressure and thus the medium is desorbed from the second bed 7462. The desorbed medium leaves the pressure swing adsorption unit 746 via passage 55 as the product fluid of the recycling system R. When the adsorption in the first bed 7461 and the desorption in the second bed 7462 are completed, the pressure swing adsorption unit 746 proceeds to the next cycle, in which the first bed 7461 is operated in a low pressure (where the medium is desorbed) and the second bed 7462 is operated in a high pressure (where the gas phase is adsorbed). When the adsorption and desorption are completed, the cycle repeats.

Suitable bed materials include zeolites and activated carbon. The switching of the pressure in the first and second beds 7461, 7462 may be achieved by a system of valves, such as shown in FIG. 7.

In the state shown in FIG. 7, the gas phase passing through the first bed 7461 may not be completely adsorbed, and thus some of the gas phase may leave the pressure swing adsorption unit 746 as waste gas 541. Alternatively, the arrangement shown in FIG. 7 may be repeated so as to provide several PSA stages. That is, instead of exhausting the waste gas 541, it may be fed into a second pressure swing adsorption unit (not shown), which may be substantially identical to the first pressure swing adsorption unit 746, so as to allow more of the medium to be extracted from the gas phase. Three or more PSA stages may be connected in series in a similar way to achieve even higher extraction efficiencies.

As shown in FIG. 7, further extraction efficiency gain may be achieved by routing a small flow from the high pressure bed (the first bed 7461 in the state shown) to the low pressure bed (the second bed 7462 in the state shown).

Using PSA, theoretically close to 100% recovery of the medium may be achieved. Furthermore, PSA may be particularly suited to the relatively small volume of medium used in lithography (small in comparison with other recycling techniques, which may be more commonly found in large-scale industries).

As noted above, the product fluid from the recycling system R may be fed back to the gas supply of the lithographic system, such as shown in FIG. 3. However, it is to be appreciated that the recycling system R may not recover 100% of the medium from the gas phase. Some of the medium may be lost as waste gas 541, or else may be lost by being dissolved in the drained liquid phase 721. Therefore, the recycled medium alone may not be enough to meet the demand by the gas supply, and the lithographic system 10 may require a top-up supply of the medium. As shown in FIG. 3, the top-up supply of medium may be combined with the recycled medium at passage 56, before being fed into the gas supply.

A gas supply may comprise a regulator module provided upstream to the fluid handling structure 12. As shown in FIG. 3, the regulator module may comprise a regulator valve 76, which may control the gas supplied the fluid handling structure 12, which may in turn control the strength of the gas jet. A more elaborate regulator module may be provided in accordance with European patent application number 23156328.9 (filed on 13 Feb. 2023).

As noted above, as an alternative to feeding the product fluid back to the gas supply, the product fluid may instead be processed into another substance. That is, the medium extracted by the recycling system R may be converted into a second, different, medium 542. For example, where carbon dioxide is used in the first medium, the second medium 542 may comprise methanol or formic acid. As shown in FIG. 4, the fluid handling system 1 may comprise a conversion unit 74A, configured to receive the product fluid and to convert the medium in the product fluid into the second medium 542. As shown, the conversion unit 74A may receive the product fluid without first purifying it by a gas phase processing unit 74 such as shown in FIGS. 5 to 7. That is, the conversion unit 74A may be capable of processing the medium in a relatively impure form, which may include unwanted gasses such as nitrogen and oxygen, as well as vapour of the immersion liquid. Nevertheless, similar to the arrangement shown in FIG. 3, a separator 72 may be provided to substantially remove the liquid phase from the two-phase fluid. Waste gasses 541 may be exhausted from the conversion unit 74A. The conversion unit 74A may comprise an electroliser or a catalytic reactor.

Embodiments also include other techniques for reducing the amount carbon dioxide required by lithographic processes.

In known techniques, carbon dioxide is continuously supplied during both the production and the non-production states of the lithographic apparatus. The carbon dioxide requirement of the lithographic apparatus due to the supply to the fluid handling structure 12 alone may be about 10 kg of carbon dioxide per hour.

Embodiments include controlling the supply of carbon dioxide to the fluid handling structure 12 so as to reduce the amount of carbon dioxide that is supplied to the fluid handling structure 12. The supply of carbon dioxide to the fluid handling structure 12 may be controlled by a Mass Flow Controller (MFC) and/or valve system. Embodiments include only supplying carbon dioxide to the fluid handling structure 12 when the lithographic apparatus is in a production state, i.e. lithographic processes are being performed. The supply of carbon dioxide to the fluid handling structure 12 may be stopped whenever the lithographic apparatus is in a non-production state, i.e. when no lithographic processes are being performed. The supply of carbon dioxide to the fluid handling structure 12 may also be stopped whenever the lithographic apparatus is in a transition state, i.e. when it is changing between a production and a non-production state, and vice-versa. If a supply of carbon dioxide to the fluid handling structure 12 is required when the lithographic apparatus is in a transition state, embodiments include implementing changes for reducing the times required for the transient states so as to reduce the overall carbon dioxide consumption.

Embodiments also include using a different gas from carbon dioxide in lithographic processes, or supplying no gas at all during lithographic processes. In particular, the gas supplied to the fluid handling structure 12 may be extremely clean dry air (XCDA). The use of XCDA, or no gas, instead of carbon dioxide may reduce the accuracy of the lithographic processes. However, the reduced accuracy may be tolerable if non-critical features and/or features with non-stringent manufacturing tolerances are being made by the lithographic processes.

Embodiments include supplying only carbon dioxide to the fluid handling structure 12 when features are being manufactured for which the required defectivity rate is low. XCDA, or no gas, may be supplied to the fluid handling structure 12 when features are being manufactured for which the required accuracy of the lithographic processes is less stringent.

Embodiments include using a model to determine changes to the operational data of processes so as to reduce the carbon dioxide requirements. The model may be executed in a computer system. The computer system may also generate and send control instructions for implementing changes determined by the model. The computer system may be comprised by the controller 500. Alternatively, the computer system may be separate from the controller 500.

The model may receive user defined instructions on the relative importance of throughput, defectivity rate, accuracy (i.e. overlay performance) and sustainability in the performed processes.

The model may then determine the operational data so as to improve the performed processes given the user defined instructions as well as the specific circumstances, as defined by the exposure recipe, substrate W properties etc.

In a first example of the user defined instructions, the lowest achievable defectivity rate is required. The model may then attempt to determine the fastest achievable route and operating conditions that also provide the lowest achievable defectivity rate. This may involve slowing down the relative movement between the substrate W and fluid handling structure 12 at specific locations and supplying only carbon dioxide to the fluid handling structure 12.

In a second example of the user defined instructions, the defectivity rate does not need to be as low as achievable and improved sustainability of the processes is preferred. The model may determine that the gas supply to the fluid handling structure 12 may be XCDA instead of carbon dioxide, or for there to be no supplied gas. The model may then attempt to determine the achievable fastest route and operational conditions that also provide the specified defectivity rate.

In all situations, the model may determine that, when the lithographic apparatus is idle or performing actions such as conditioning moves that are not defectivity critical, the gas supply to the fluid handling structure 12 should be switched off to avoid unnecessary use of carbon dioxide. Conditioning moves are moves that are performed when the lithographic apparatus is in a non-production state to maintain an appropriate operating temperature.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools.

Although specific reference may have been made above to the use of embodiments of the invention in the context of optical lithography, it will be appreciated that the invention, where the context allows, is not limited to optical lithography.

Aspects of the invention are described in the following numbered clauses.
1. A fluid handling system (1) for a lithographic system (10), the fluid handling system comprising: a liquid supply configured to supply an immersion liquid to fill at least a portion of an immersion space (11) between a substrate (W) and a projection system (PS) of the lithographic system, wherein the projection system is configured project a patterned radiation beam (B) onto the substrate;
   a gas supply configured to generate a gas jet for confining the immersion liquid within the immersion space, wherein the gas jet comprises a medium; and an evacuation system comprising an evacuation passage (51), wherein the evacuation system is configured to draw a two-phase fluid comprising the medium and the immersion liquid into the evacuation passage, and the two-phase fluid comprises a gas phase and a liquid phase;
      a recycling system (R) configured to receive the two-phase fluid from the evacuation passage, and to extract the medium from the two-phase fluid as a product fluid for further use.
2. The fluid handling system of clause 1, wherein the medium comprises carbon dioxide, optionally humidified carbon dioxide.
3. The fluid handling system of clauses 1 or 2, wherein the immersion liquid comprises water, optionally Ultra-Pure Water.
4. The fluid handling system of any one of the preceding clauses, wherein the recycling system comprises a separator (72) configured to separate the gas phase from the two-phase fluid, and the recycling system is configured to extract the medium from the gas phase.
5. The fluid handling system of clause 4, wherein the recycling system further comprises a compressor (741) configured to compress the gas phase.
6. The fluid handling system of any one of the preceding clauses, wherein the recycling system comprises a gas dryer (742) configured to reduce the relative humidity of the gas phase.
7. The fluid handling system of any one of the preceding clauses, wherein the recycling system is configured to increase the volumetric concentration of the medium in the product fluid, as measured at 1013 mbar absolute and 0° C., to at least 99.9%, optionally at least 99.99%, optionally about 99.998%.
8. The fluid handling system of any one of the preceding clauses, wherein the recycling system comprises a liquefaction unit (743) configured to increase the concentration of the medium in the product fluid and, optionally, to output the product fluid in liquid form.
9. The fluid handling system of any one of clauses 1 to 7, wherein the recycling system comprises a membrane separation unit (745) configured to increase the concentration of the medium in the product fluid.
10. The fluid handling system of any one of clauses 1 to 7, wherein the recycling system comprises a pressure swing adsorption unit (746) configured to increase the concentration of the medium in the product fluid.
11. The fluid handling system of any one of the preceding clauses, further configured to feed the product fluid from the recycling system back to the gas supply of the lithographic system.
12. The fluid handling system of any one of the preceding clauses, further comprising a conversion system (74A) configured to receive the product fluid and to convert the medium in the product fluid into a second, different, medium (542); wherein, optionally, the second medium comprises one of methanol and formic acid.
13. The fluid handling system of any one of the preceding clauses, further comprising a mass flow controller and/or valve system configured so that the gas supplied to gas supply is controllable to be carbon dioxide, extremely clean dry air, or for no gas to be supplied to the gas supply.
14. The fluid handling system of clause 13, further comprising a computer system configured to determine control instructions for the mass flow controller and/or valve system, to thereby control the operation of the gas supply, in dependence on a model; wherein the model is configured to determine the control instructions in dependence on user-defined specifications of defectivity rate, accuracy, throughput and sustainability.
15. A method comprising: supplying an immersion liquid to fill at least a portion of an immersion space between a substrate and a projection system of a lithographic system, which projection system projects a patterned radiation beam onto the substrate;
   supplying gas to generate a gas jet which confines the immersion liquid within the immersion space, wherein the gas jet comprises a medium;
   drawing a two-phase fluid comprising the medium and the immersion liquid into an evacuation passage, wherein the two-phase fluid comprises a gas phase and a liquid phase; and extracting the medium from the two-phase fluid as a product fluid for further use.
16. The method of clause 15, wherein the medium comprises carbon dioxide, optionally humidified carbon dioxide.
17. The method of clause 15 or 16, wherein the immersion liquid comprises water, optionally Ultra-Pure Water.
18. The method of any one of clauses 15 to 17, further comprising separating the gas phase from the two-phase fluid; and, in the step of extracting the medium, the medium is extracted from the gas phase.
19. The method of clause 18, further comprising compressing the gas phase.
20. The method of any one of clauses 15 to 19, further comprising reducing the relative humidity of the gas phase.
21. The method of any one of clauses 15 to 20, further comprising increasing the volumetric concentration of the medium in the product fluid, as measured at 1013 mbar absolute and 0° C., to at least 99.9%, optionally at least 99.99%, optionally about 99.998%.
22. The method of any one of clauses 15 to 21, further comprising increasing the concentration of the medium in the product fluid by liquefaction and, optionally, outputting the product fluid in liquid form.
23. The method of any one of clauses 15 to 21, further comprising increasing the concentration of the medium in the product fluid by membrane separation.
24. The method of any one of clauses 15 to 21, further comprising increasing the concentration of the medium in the product fluid by pressure swing adsorption.
25. The method of any one of clauses 15 to 24, further comprising feeding the product fluid back to the lithographic apparatus so as to supply the gas to generate the gas jet.
26. The method of any one of clauses 15 to 25, further comprising converting the medium in the product fluid into a second, different, medium; wherein, optionally, the second medium comprises one of methanol and formic acid.
27. The method of any one of clauses 15 to 26, wherein the supplied gas is controllable to be carbon dioxide, extremely clean dry air, or for no gas to be supplied.
28. The method of clause 27, further comprising determining control instructions for the supply of the gas in dependence on a model; wherein the model is configured to determine the control instructions in dependence on user-defined specifications of defectivity rate, accuracy, throughput and sustainability.
29. A method of manufacturing devices using the lithographic system of any one of clauses 1 to 14.
30. A method of manufacturing devices comprising the method of any one of clauses 15 to 28.

While specific embodiments of the invention have been described above, it will be appreciated that the invention may be practiced otherwise than as described. The descriptions above are intended to be illustrative, not limiting. Thus, it will be apparent to one skilled in the art that modifications may be made to the invention as described without departing from the scope of the claims set out below.

1. A fluid handling system for a lithographic system, the fluid handling system comprising:
a liquid supply configured to supply an immersion liquid to fill at least a portion of an immersion space between a substrate and a projection system of the lithographic system;
a gas supply configured to generate a gas jet for confining the immersion liquid within the immersion space, wherein the gas jet comprises a medium;
an evacuation system comprising an evacuation passage, wherein the evacuation system is configured to draw a two-phase fluid comprising the medium and the immersion liquid into the evacuation passage, and the two-phase fluid comprises a gas phase and a liquid phase; and
a recycling system configured to receive the two-phase fluid from the evacuation passage, and to extract the medium from the two-phase fluid as a product fluid for further use, wherein the recycling system comprises a compressor configured to compress the gas phase.

2. The fluid handling system of claim 1, wherein the medium comprises carbon dioxide.

3. The fluid handling system of claim 1, wherein the recycling system comprises a separator configured to separate the gas phase from the two-phase fluid, and the recycling system is configured to extract the medium from the gas phase.

4. The fluid handling system of claim 1, wherein the recycling system comprises a gas dryer configured to reduce the relative humidity of the gas phase, and/or wherein the recycling system is configured to increase the volumetric concentration of the medium in the product fluid, as measured at 1013 mbar absolute and 0° C., to at least 99.9%, and/or wherein the recycling system comprises a liquefaction unit configured to increase the concentration of the medium in the product fluid, and/or wherein the recycling system comprises a membrane separation unit configured to increase the concentration of the medium in the product fluid, and/or wherein the recycling system comprises a pressure swing adsorption unit configured to increase the concentration of the medium in the product fluid.

5. The fluid handling system of claim 1, further comprising a mass flow controller and/or valve system configured so that the gas supplied to gas supply is controllable to be at least two selected from: carbon dioxide, extremely clean dry air, or for no gas to be supplied to the gas supply.

6. The fluid handling system of claim 5, further comprising a computer system configured to determine control instructions for the mass flow controller and/or valve system, to control the operation of the gas supply, in dependence on a model, wherein the model is configured to determine the control instructions in dependence on user-defined specifications of defectivity rate, accuracy, throughput and sustainability.

7. A lithographic system comprising the fluid handling system of claim 1.

8. A method comprising:
supplying an immersion liquid to fill at least a portion of an immersion space between a substrate and a projection system of a lithographic system, which projection system projects a patterned radiation beam onto the substrate;
supplying gas to generate a gas jet which confines the immersion liquid within the immersion space, wherein the gas jet comprises a medium;
drawing a two-phase fluid comprising the medium and the immersion liquid into an evacuation passage, wherein the two-phase fluid comprises a gas phase and a liquid phase; and
extracting the medium from the two-phase fluid as a product fluid for further use, wherein the extracting comprises compressing the gas phase.

9. The method of claim 8, wherein the medium comprises carbon dioxide and/or further comprising separating the gas phase from the two-phase fluid.

10. The method of claim 8, further comprising reducing the relative humidity of the gas phase, and/or further comprising increasing the volumetric concentration of the medium in the product fluid, as measured at 1013 mbar absolute and 0° C., to at least 99.9%.

11. The method of any of claim 8, further comprising increasing the concentration of the medium in the product fluid by liquefaction or further comprising increasing the concentration of the medium in the product fluid by membrane separation, or further comprising increasing the concentration of the medium in the product fluid by pressure swing adsorption.

12. The method of claim 8, wherein the supplied gas is controllable to be at least two selected from: carbon dioxide, extremely clean dry air, or for no gas to be supplied.

13. The method of claim 12, further comprising determining control instructions for the supply of the gas in dependence on a model, wherein the model is configured to determine the control instructions in dependence on user-defined specifications of defectivity rate, accuracy, throughput and sustainability.

14. A method of manufacturing devices using the lithographic system of claim 7.

15. A method of manufacturing devices comprising the method of claim 8.

16. The method of claim 8, further comprising converting the medium in the product fluid into a second, different, medium.

17. The fluid handling system of claim 1, further comprising a conversion system configured to receive the product fluid and to convert the medium in the product fluid into a second, different, medium.

18. A fluid handling system for a lithographic system, the fluid handling system comprising:
a liquid supply configured to supply an immersion liquid to fill at least a portion of an immersion space between a substrate and a projection system of the lithographic system;
a gas supply configured to generate a gas jet for confining the immersion liquid within the immersion space, wherein the gas jet comprises a medium;
an evacuation system comprising an evacuation passage, wherein the evacuation system is configured to draw a two-phase fluid comprising the medium and the immersion liquid into the evacuation passage, and the two-phase fluid comprises a gas phase and a liquid phase; and
a recycling system configured to receive the two-phase fluid from the evacuation passage, and to extract the medium from the two-phase fluid as a product fluid for further use, while substantially preventing gas and liquid from being introduced to the two-phase fluid prior to extraction of the product fluid.

19. The fluid handling system of claim 18, wherein the recycling system comprises a gas dryer configured to reduce the relative humidity of the gas phase, and/or wherein the recycling system is configured to increase the volumetric concentration of the medium in the product fluid, as measured at 1013 mbar absolute and 0° C., to at least 99.9%, and/or wherein the recycling system comprises a liquefaction unit configured to increase the concentration of the medium in the product fluid, and/or wherein the recycling system comprises a membrane separation unit configured to increase the concentration of the medium in the product fluid, and/or wherein the recycling system comprises a pressure swing adsorption unit configured to increase the concentration of the medium in the product fluid.

20. The fluid handling system of claim 18, further comprising a mass flow controller and/or valve system configured so that the gas supplied to gas supply is
